(19) United States
(12) Patent Application Publication
(10) Pub. No.: US 2008/0180180 A1
(43) Pub. Date: Jul. 31, 2008

(54) FREQUENCY SYNTHESIZER AND METHOD FOR OPERATING A FREQUENCY SYNTHESIZER

(76) Inventors: Thomas Musch, Mulheim/Ruhr (DE); Burkhard Schiek, Bochum (DE); Michael Gerding, Herne (DE)

Correspondence Address: CESARI AND MCKENNA, LLP, 88 BLACK FALCON AVENUE, BOSTON, MA, 02210, US

(21) Appl. No.: 12/053,736

(22) Filed: Mar. 24, 2008

Related U.S. Application Data
(63) Continuation of application No. 11/167,670, filed on Jun. 27, 2005, now abandoned.

(30) Foreign Application Priority Data
Jul. 1, 2004 (DE) 2004 032 130.2

(51) Int. Cl. H03B 19/00; H03B 21/00

(52) U.S. Cl. 331/37

(57) ABSTRACT

A frequency synthesizer, especially for use with a time-base generator of a fill-level meter employing the radar principle is designed to output a first frequency signal and a second frequency signal at mutually slightly different frequencies. The synthesizer incorporates a reference oscillator operating at a reference frequency and a control oscillator regulated at a control frequency. A first frequency divider with a division factor V₁ is connected in line with the reference oscillator and a second frequency divider with the division factor V₂ is connected in line with the control oscillator, which frequency dividers serve to output the first frequency signal and the second frequency signal, respectively. The result is a stable frequency synthesizer with a large phase-control bandwidth and consequently an extremely short transient response time as well as broad-band phase-noise suppression. A method for operating the synthesizer is also disclosed.

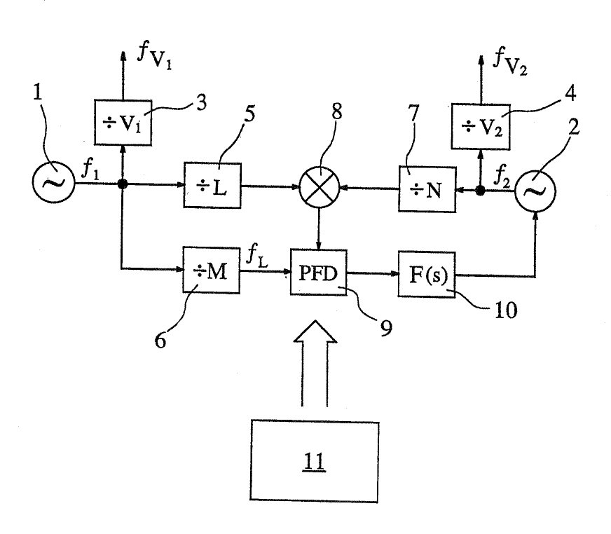

### BACKGROUND OF THE INVENTION

This invention relates to a frequency synthesizer, especially for use with a time-base generator of a fill-level meter employing the radar principle, for outputting a first frequency signal and a second frequency signal at mutually slightly different frequencies, incorporating a reference oscillator operating at a reference frequency and a control oscillator regulated at a control frequency. The invention further relates to a method for operating a frequency synthesizer, especially for use with a time-base generator of a fill-level meter employing the radar principle, for outputting a first frequency signal and a second frequency signal at mutually slightly different frequencies, incorporating a reference oscillator operating at a reference frequency and a control oscillator regulated at a control frequency.

A frequency synthesizer of this type and a corresponding method for operating a frequency synthesizer have been disclosed earlier, for instance, in DE 102 44 348 A1. Specifically, that document describes a frequency synthesizer in which the control oscillator and its control frequency are tied to the reference frequency of the reference oscillator in such fashion that there is a slight frequency differential between the control frequency and the reference frequency without that being at the expense of a narrow standard frequency. In practice it has been found, however, that the stability attainable with that type of frequency synthesizer and the associated noise pattern could bear some improvements.

### SUMMARY OF THE INVENTION

It is therefore the objective of this invention to introduce a frequency synthesizer and a method for operating a frequency synthesizer by means of which stable operation of the frequency synthesizer is attainable.

Based on the above concept of a frequency synthesizer, this objective is achieved by connecting a first frequency divider with a division factor V₁ in line with the reference oscillator and a second frequency divider with the division factor V₂ in line with the control oscillator, which frequency dividers serve to output the first frequency signal and the second frequency signal, respectively.

Thus, according to the invention, it is not the reference frequency and the control frequency that directly serve to output the first frequency signal and second frequency signal between which there is to be a slight frequency differential, but, instead, it is signals whose frequencies have been divided down relative to the control frequency and reference frequency. In a preferred implementation of the invention, this is accompanied by a provision whereby the division factor V₁ differs from the division factor V₂. In a particularly preferred embodiment of the invention, the ratio between the division factor V₁ and the division factor V₂ is such that the quotient provides two small integers which integers are preferably smaller than 20 and most desirably smaller than 10.

In this preferred embodiment of the invention, the reference oscillator and control oscillator operate at distinctly different frequencies, in contrast to the prior art from which this invention has evolved and in which the reference frequency and the control frequency are very close together. One of the advantages of this is the fact that there is far less mutual interference through cross-coupling between the two oscillators, i.e. between the reference oscillator and the control oscillator, than in prior-art designs.

The control oscillator can be coupled to the reference oscillator in different ways including prior-art techniques. In a preferred embodiment of the invention, the reference oscillator, for outputting the reference frequency signal, connects to a third frequency divider with a division factor L as well as to a fourth frequency divider with a division factor M, while for outputting the control frequency signal, the control oscillator connects to a fifth frequency divider with a division factor N, a mixer is provided which, for feeding-in the frequency signal emitted by the third frequency divider and the frequency signal emitted by the fifth frequency divider, connects to the third frequency divider and to the fifth frequency divider, and a phase frequency discriminator is provided which, for feeding-in the mixed differential frequency signal emanating from the mixer, connects to the mixer and, for feeding-in the standard frequency signal emitted by the fourth frequency divider, connects to that fourth frequency divider, while for feeding-in the frequency signal emitted by the phase frequency discriminator, the control oscillator connects to the phase frequency discriminator preferably via a loop filter.

As a particular feature in a preferred embodiment of the invention, the differential frequency i.e. the difference between the frequency of the first frequency signal and the frequency of the second frequency signal is set smaller than the standard frequency—i.e. the frequency of the standard frequency signal emitted by the third frequency divider—by a factor of at least 10, preferably by a factor of at least 30 and most desirably by a factor of 100.

In addition, a preferred embodiment of the invention provides for the division factors to be selected in a way as to arrive at an integral term of

V₁ N L±V₁ M N−V₂ M L

preferably amounting to 1. The resulting advantages are explained in the detailed description that follows of a preferred embodiment of the invention with reference to the attached drawing.

In terms of the method referred to above for operating a frequency synthesizer, the stated objective is achieved by making the difference between the reference frequency and the control frequency at least one order of magnitude larger than the frequency differential between the first frequency signal and the second frequency signal.

Thus, an essential element of this innovative method for operating a frequency synthesizer consists in the fact that, in contrast to prior art, the two oscillations are driven not at nearly identical, but at substantially different, frequencies. As part of that approach, a preferred embodiment of the invention provides for the reference frequency signal emitted by the reference oscillator for generating the first frequency signal to be divided by the division factor V₁ and for the control frequency signal emitted by the control oscillator for generating the second frequency signal to be divided by the division factor V₂. Moreover, as already mentioned above in connection with the frequency synthesizer according to this invention, the division factors in a preferred embodiment of the invention differ from each other, representing two small integers relative to each other, which integers are preferably smaller than 20 and ideally smaller than 10.

A preferred implementation of the invention further includes a first frequency divider with the division factor V₁ for dividing the reference frequency signal and a second frequency divider with the division factor V₂ for dividing the control frequency signal. Moreover, a preferred implementation of the invention includes a feature whereby the reference oscillator outputs the reference frequency signal to a third frequency divider with a division factor L and to a fourth frequency divider with a division factor M while the control oscillator outputs the control frequency signal to a fifth frequency divider with a division factor N, and a mixer that receives the frequency signal emitted by the third frequency divider as well as the frequency signal emitted by the fifth frequency divider, as well as a phase frequency discriminator to which the mixed differential frequency signal emanating from the mixer and the standard frequency signal emitted by the fourth frequency divider are fed, while the frequency signal emanating from the phase frequency discriminator is fed to the control oscillator preferably via a loop filter. Apart from that, of course, there are other, prior-art approaches by which the frequencies of the control oscillator and the reference oscillator can be paired up in predefined fashion.

In another preferred embodiment of the invention, the frequency differential is smaller than the standard frequency by a factor of at least 10, preferably by a factor of at least 30 and most desirably by a factor of at least 100. Apart from that, it is particularly desirable for the division factors to be selected in a way as to arrive at an integral term of

V₁ N L±V₁ M N−V₂ M L

most preferably amounting to 1.

Frequency synthesizers of the type described above should also permit operation in a two-wire system such as a two-wire level meter. The two-wire systems referred to are those which, by way of a dual-conductor interface, permit the simultaneous transmission of their measuring signal and the input of electric power. The measuring signal is typically transmitted by a current in the range between 4 and 20 mA with a voltage, for instance, of 24 VDC. For an output of the smallest measured value, that being 4 mA, the available electric power is only just under 100 mW. This electric power limitation in two-wire systems requires provisions for restricting the power consumption of these two-wire systems to where it is still possible to initiate and maintain a measuring operation.

Accordingly, another objective of the invention is to provide a frequency synthesizer suitable for two-wire operation as well as a corresponding method for operating such a frequency synthesizer.

For the frequency synthesizer described above, this objective is achieved by means of a drive unit for the intermittent operation of the frequency synthesizer with a transient rise time of less than 50 ms.

Thus, according to the invention, the frequency synthesizer is not operated continuously but is powered up only when, in fact, a measuring operation is to be initiated. Especially when the novel frequency synthesizer is used with a time-base generator of a fill-level meter employing the radar principle, it is important for the transient rise time to be sufficiently short, meaning less than 50 ms. This is due to the fact that typical measuring times range from 200 ms to as short as 10 ms. A preferred implementation of the invention, therefore, provides for the drive unit for the intermittent operation of the frequency synthesizer to permit a transient rise time of less than 25 ms, preferably less than 10 ms and most desirably less than 5 ms.

A preferred embodiment the invention incorporates a frequency divider with a division factor V₁ and a second frequency divider with a division factor V₂, of which the first frequency divider connects to the reference oscillator for feeding-in the reference frequency signal and the second frequency divider connects to the control oscillator for feeding-in the control frequency signal, the first frequency divider serving to output the first frequency signal and the second frequency divider serving to output the second frequency signal.

In a preferred configuration of the invention, the inclusion of the aforementioned frequency dividers is further expanded in that, for outputting the reference frequency signal, the reference oscillator connects to a third frequency divider with a division factor L and to a fourth frequency divider with a division factor M, that for outputting the control frequency signal the control oscillator connects to a fifth frequency divider with a division factor N, that a mixer is provided which, for feeding-in the frequency signal emitted by the third frequency divider and the frequency signal emitted by the fifth frequency divider, connects to the first frequency divider and to the second frequency divider, and that a phase frequency discriminator is provided which, for feeding-in the mixed differential frequency signal, connects to the mixer and which, for feeding-in the standard frequency signal emitted by the fourth frequency divider, connects to the fourth frequency divider, while for feeding-in the frequency signal emanating from the phase frequency discriminator, the control oscillator connects to the phase frequency discriminator preferably via a loop filter.

The frequency difference is preferably set lower than the standard frequency by a factor of at least 10, preferably by a factor of at least 30 and most desirably by a factor of 100. In a preferred implementation of the invention, the division factors are selected in a way as to arrive at an integral term of

V₁ N L±V₁ M N−V₂ M L

most preferably amounting to 1.

In terms of the above-described method for operating a frequency synthesizer, the above-stated objective, that being the provision of a method for operating a frequency synthesizer that is also suitable for two-wire operation, is achieved by driving the frequency synthesizer intermittently with a transient rise time of less than 50 ms.

Preferred versions of the innovative method correspond in analogous fashion to the above-described embodiments of the novel frequency synthesizer as adapted for two-wire operation.

There are numerous ways in which the frequency synthesizer according to this invention and the innovative method for operating the frequency synthesizer can be configured and enhanced. In this context, attention is invited to the dependent claims, and to the following detailed description of a preferred embodiment of the invention, with reference to the attached drawing.

### BRIEF DESCRIPTION OF THE DRAWING

In the drawing, the single FIGURE is a schematic illustration of the configuration of a frequency synthesizer according to a preferred embodiment of the invention.

### DETAILED DESCRIPTION OF AN ILLUSTRATIVE EMBODIMENT

The depicted frequency synthesizer according to the preferred embodiment of the invention lends itself particularly well to being used with a time-base generator of a fill-level meter employing the radar principle. A level meter of that type may be based, for instance, on the TDR (time domain reflectometry) measuring principle. The TDR measuring principle has been used, for instance, in cable testing and somewhat resembles the operating mode of radar equipment. In a TDR-type level meter, an extremely short electrical pulse is transmitted via one or two essentially linear electric conductors into a container holding a medium such as a liquid, a powder or granules whose fill level is to be determined. The short electrical pulse transmitted via the two conductors into the container is reflected on the surface of the medium and the retroreflected portion of the short electrical pulse is detected by a measuring transducer of the measuring instrument. The retroreflected portion of the short electrical pulse is a function of the dielectric coefficient, i.e. relative permittivity, of the medium and increases in parallel with the latter. The runtime of the signal is proportional to the distance between the measuring transducer and the surface of the medium in the container. Variable ambient conditions such as increasing or decreasing atmospheric pressure or a temperature increase or drop do not affect the measuring accuracy of the TDR level meter. Also, the runtime of the signal is unaffected by the dielectric coefficient of the medium reflecting it.

In other words, the TDR measuring principle is based on the measurement of the often very short runtimes of an electromagnetic signal. If the medium in the container is nearly at the full level, with the surface of the medium extending for instance only 15 cm below the measuring transducer of the TDR level meter, the total distance traveled by the electromagnetic pulse from the measuring transducer to the surface of the medium and back will be only 30 cm, which translates into a runtime of the short electrical pulse of 1 ns. To be able to measure such short runtimes at all requires the use of a sampling process for which two high-frequency signals are generated at predefined, mutually slightly different frequencies. The measurement is initiated at time 0, the point at which both frequency signals oscillate in-phase. The signal oscillating at the higher frequency provides the clock pulse for the transmission of the actual measuring signal, i.e. of the short electrical pulse, into the container. For example, it is always at the start of a cycle of the signal oscillating at the higher frequency that a short electrical pulse is generated and transmitted into the container. The signal oscillating at the lower frequency trails the higher-frequency signal by a specific, small amount per oscillation cycle. This defines a timing pattern that constitutes a digital time base serving as the means for measuring the runtime of the short electrical signal that has been transmitted into the container and reflected by the surface of the medium therein.

The frequency synthesizer according to the preferred embodiment of the invention described here lends itself particularly well to being used with a time-base generator for a level meter such as a TDR-type level meter, while at the same time offering the possibility of a two-wire operation, as described in detail below.

As depicted in the single FIGURE attached hereto, the frequency synthesizer according to the preferred embodiment of the invention is configured as follows. A reference oscillator 1 is operated at a reference frequency f₁, thus providing what may be termed the reference for a control oscillator 2 that is coupled to the reference oscillator 1, insofar as it regulates the control oscillator 2 to a control frequency f₂ as explained below. It should first be mentioned that a first frequency divider 3 with a division factor V₁ is connected in line with the reference oscillator 1 and a second frequency divider 4 with a division factor V₂ is connected in line with the control oscillator 2, these frequency dividers serving to output the first frequency signal f_{V1} and, respectively, the second frequency signal f_{V2}. Between the first frequency signal f_{V1} and the second frequency signal f_{V2}, there is the aforementioned slight frequency difference that is needed for the time-base generator of the level meter.

The frequency synthesizer according to the preferred embodiment of the invention described here is functionally configured in a way that for outputting the reference frequency signal f₁, the reference oscillator 1 connects to a third frequency divider 5 with a division factor L as well as to a fourth frequency divider 6 with a division factor M, while for outputting the control frequency signal f₂, the control oscillator 2 connects to a fifth frequency divider 7 with a division factor N. A mixer 8 is provided which, for feeding-in the frequency signal emitted by the third frequency divider 5 and the frequency signal emitted by the fifth frequency divider 7, connects to the third frequency divider 5 and to the fifth frequency divider 7, and a phase frequency discriminator 9 is provided which, for feeding-in the mixed differential frequency signal emanating from the mixer 8, connects to the mixer 8 and, for feeding-in the standard frequency signal fL emitted by the fourth frequency divider 6, connects to that fourth frequency divider 6, while for feeding-in the frequency signal emitted by the phase frequency discriminator 9 the control oscillator 2 connects to the phase frequency discriminator 9 via a loop filter 10. The division factors selected are as follows: M=9, N=11 and L=496 or 494, V1=5 and V2=6. The reference oscillator 2 operates at a frequency of 20 MHz, the result being as follows.

In the transient response state, the frequency f₂ of the control oscillator 2 will be:

$${f}_{2} = {f}_{1} ( \frac{N}{M} \pm \frac{N}{L} ) ,$$

in case the control frequency f₂ is higher than the reference frequency f₁. The sign depends on the frequency conditions in the mixer 8; the positive sign must be selected if

$$\frac{{f}_{2}}{N} > \frac{{f}_{1}}{M}$$

while the negative sign must be used if

$$\frac{{f}_{2}}{N} < \frac{{f}_{1}}{M}$$

If L=496, the control frequency will be

$${f}_{2} = {f}_{1} \cdot N ( \frac{L - M}{ML} ) = 24 MHz + 896.05 Hz ,$$

whereas, if L=494 has been selected, the control frequency will be

$${f}_{2} = {f}_{1} \cdot N ( \frac{L - M}{ML} ) = 24 MHz - 899.686 Hz .$$

In the case where L=496, the differential frequency will be

f_{V2}−f_{V1}=149.342 3̅ Hz

and if L=494, it will be

f_{V1}−f_{V2}=149.947 6̅ Hz.

Thus, the resulting frequency differential between the first frequency signal and the second frequency signal will be small at 150 Hz, without the need to also operate the reference oscillator 1 and the control oscillator 2 at such frequencies with a correspondingly small frequency differential between them. Instead, in the case described, the reference oscillator 1 is operated at 20 MHz and the control oscillator 2 is regulated at about 24 MHz, thus leaving a substantially larger difference between the reference frequency and the control frequency, which, in turn, reduces cross-coupling interference between the control oscillator 2 and the reference oscillator 1.

For the frequency synthesizer according to the preferred embodiment of the invention here described, another consideration is of great importance.

Looking at the differential frequency Δf in the prior-art case, where the control frequency is virtually identical to the reference frequency, meaning that no frequency dividers 3, 4 are connected in line with the reference oscillator 1 and the control oscillator 2, the situation will be as follows:

$$\begin{matrix}Δ f = \vert {f}_{1} - {f}_{2} \vert \\ = \vert {f}_{1} - {f}_{1} N ( \frac{L - M}{LM} ) \vert \\ = {f}_{1} \cdot \vert \frac{ML - NL - MN}{ML} \vert\end{matrix}$$

The resulting condition for the prior-art solution is thus that ML−NL−MN be an integral term, preferably amounting to 1, so as to obtain the smallest possible frequency differential Δf.

For the frequency synthesizer according to the preferred embodiment of the invention here described, the differential frequency will be

$$Δ f = {f}_{1} \vert \frac{1}{{V}_{1} {V}_{2} ML} \vert ,$$

in which case, as small a frequency differential as possible is obtained by setting the numerator at 1 from the start. The corresponding condition in this case is

V₁ M L±V₁ N M−V₂ N L=±1.

The result is the smallest possible differential frequency Δf. In other words, for a predefined differential frequency Δf that is essentially identical, for instance, to the differential frequency Δf described in prior art, lower values for the division factors M, N and L will suffice to arrive at the same result. Small values for these division factors, after all, contribute significantly to the ability to enlarge the bandwidth of the phase control and thus to the advantages described further below.

Another factor of significance in this case is that the standard frequency f1 will be

$${f}_{L} = \frac{{f}_{1}}{L} .$$

It follows that in the prior-art case in which no frequency dividers 3, 4 are connected in line with the reference oscillator 1 and the control oscillator 2, respectively, and in which the reference oscillator 1 and the control oscillator 2 are operated at closely neighboring frequencies, the differential frequency is smaller by only the factor M than is the standard frequency. By contrast, in the case of the frequency synthesizer according to the preferred embodiment of the invention here described, the differential frequency relative to the standard frequency is significantly smaller still, by the factor V1V2M. Given the values stated above for V1 and V2, at 6 and 9, respectively, the differential frequency will be lower than the standard frequency by a factor of 270.

This allows for a substantially larger phase-control bandwidth than is attainable in the prior art, resulting at once in a considerably shorter transient response time and in a broad-band phase-noise suppression of the oscillator. Less phase noise, in turn, means less “grid”, which benefits the stability of the frequency synthesizer.

As has already been referred to further above, the frequency synthesizer according to the preferred embodiment of the invention described here is also suitable for two-wire operation, i.e. an operation with a limited maximum voltage, for instance, of 24 VDC and a current in the range from 4 to 20 mA, that current serving to indicate the measured value concerned. The associated problem whereby for outputting the smallest measured value at 4 mA, the electric power available is less than 100 mW can be overcome by operating the frequency synthesizer, according to the preferred embodiment of the invention, in an intermittent mode.

For that purpose, as shown in the single drawing figure, a drive unit 11 is provided by means of which it is possible to operate the frequency synthesizer intermittently with a transient response time of less than 5 ms. One reason why such a short transient response time can be realized with the frequency synthesizer according to the preferred embodiment of this invention is the larger phase-control bandwidth. Specifically, in this particular case a transient response time of less than 5 ms is attainable, while in the prior art, the transient response time has been around 300 ms under the best of circumstances.

What is claimed is:

1. A frequency synthesizer, especially for use with a time-base generator of a fill-level meter employing the radar principle, for outputting a first frequency signal and a second frequency signal at mutually slightly different frequencies, said synthesizer incorporating a reference oscillator operating at a reference frequency and a control oscillator regulated at a control frequency, the improvement wherein a first frequency divider with a division factor V₁ is connected in line with the reference oscillator and a second frequency divider with the division factor V₂ is connected in line with the control oscillator, which frequency dividers serve to output the first frequency signal and the second frequency signal, respectively.

2. The frequency synthesizer as in claim 1, wherein for outputting the reference frequency signal the reference oscillator connects to a third frequency divider with a division factor L as well as to a fourth frequency divider with a division factor M, while for outputting the control frequency signal the control oscillator connects to a fifth frequency divider with a division factor N, a mixer is provided which, for feeding-in the frequency signal emitted by the third frequency divider and the frequency signal emitted by the fifth frequency divider, connects to the third frequency divider and to the fifth frequency divider, and that a phase frequency discriminator is provided which, for feeding-in the mixed differential frequency signal emanating from the mixer, connects to the mixer and, for feeding-in the standard frequency signal emitted by the fourth frequency divider, connects to said fourth frequency divider, while for feeding-in the frequency signal emitted by the phase frequency discriminator, the control oscillator connects to the phase frequency discriminator preferably via a loop filter.

3. The frequency synthesizer as in claim 2, wherein the differential frequency is set lower than the standard frequency by a factor of at least 10, preferably by a factor of at least 30 and most desirably by a factor of at least 100.

4. The frequency synthesizer as in claim 2 or 3, wherein the division factors are selected in a way as to arrive at an integral term of
V₁ N L±V₁ M N−V₂ M L
preferably amounting to 1.

5. The frequency synthesizer as in claims 1 or 2, and further including a drive unit for the intermittent operation of the frequency synthesizer.

6. A method for operating a frequency synthesizer, especially for use with a time-base generator of a fill-level meter employing the radar principle, for outputting a first frequency signal and a second frequency signal at mutually slightly different frequencies, incorporating a reference oscillator operating at a reference frequency and a control oscillator regulated at a control frequency, wherein the difference between the reference frequency and the control frequency is greater by at least one order of magnitude than the frequency differential between the first frequency signal and the second frequency signal.

7. The method as in claim 6, wherein the reference frequency signal emitted by the reference oscillator for generating the first frequency signal is divided by a division factor V₁ and the control frequency signal emitted by the control oscillator for generating the second frequency signal is divided by a division factor V₂.

8. The method as in claim 7, wherein a first frequency divider with a division factor V₁ and a second frequency divider with a division factor V₂ are employed for dividing the reference frequency signal and the control frequency signal, respectively.

9. The method as in claim 8, wherein the reference oscillator outputs the reference frequency signal to a third frequency divider with a division factor L and to a fourth frequency divider with a division factor M, the control oscillator outputs the control frequency signal to a fifth frequency divider with a division factor N, a mixer is provided to which the frequency signal emitted by the third frequency divider and the frequency signal emitted by the fifth frequency divider are fed, and a phase frequency discriminator is provided to which the mixed differential frequency signal emanating from the mixer and the standard frequency signal emitted by the fourth frequency divider are fed, and the frequency signal emitted by the phase frequency discriminator is fed to the control oscillator preferably via a loop filter.

10. The method as in claim 9, wherein the differential frequency is set smaller than the standard frequency by a factor of at least 10, preferably by a factor of at least 30 and most desirably by a factor of 100.

11. The method as in claim 9 or 10, wherein the division factors are selected in a way as to arrive at an integral term of
V₁ N L±V₁ M N−V₂ M L
preferably amounting to 1.

12. The method as in one of the claims 6 to 10, wherein the frequency synthesizer is operated in intermittent fashion.
